(19) United States
(12) Patent Application Publication
(10) Pub. No.: US 2021/0336422 A1
(43) Pub. Date: Oct. 28, 2021

(54) Integrated vertical emitter structure having controlled wavelength

(71) Applicant: Apple Inc., Cupertino, CA (US)

(72) Inventors: Fei Tan, San Jose, CA (US); Arnaud Laflaquiere, Singapore (SG); Chinhan Lin, Cupertino, CA (US); Christophe Verove, Grenoble (FR); Jae Y Park, Newark, CA (US)

(21) Appl. No.: 17/228,742

(22) Filed: Apr. 13, 2021

Related U.S. Application Data
(60) Provisional application No. 63/015,754, filed on Apr. 27, 2020.

(51) Int. Cl. H01S 5/183; H01S 5/343; H01S 5/042

(52) U.S. Cl. CPC H01S 5/18377; H01S 5/18327; H01S 5/34306; H01S 5/0201; H01S 5/3432; H01S 5/34333; H01S 5/04254

(57) ABSTRACT

An optoelectronic device includes: (i) a semiconductor substrate doped with a first level of n-type dopants, (ii) a contact semiconductor layer disposed over the semiconductor substrate and doped with a second level of n-type dopants, larger than the first level, (iii) an upper distributed Bragg-reflector (DBR) stack disposed over the contact semiconductor layer and including alternating first and second epitaxial semiconductor layers having respective first and second indexes of refraction that differ from one another in a predefined wavelength band, (iv) a set of epitaxial layers disposed over the upper DBR, the set of epitaxial layers includes one or more III-V semiconductor materials and defines: (a) a quantum well structure, and (b) a confinement layer, and (v) a lower DBR stack disposed over the set of epitaxial layers, opposite the upper DBR, and including alternating dielectric and semiconductor layers.

### CROSS-REFERENCE TO RELATED APPLICATIONS

This application claims the benefit of U.S. Provisional Patent Application 63/015,754, filed Apr. 27, 2020, whose disclosure is incorporated herein by reference.

### TECHNICAL FIELD

Embodiments described herein are related generally to semiconductor devices, and particularly to methods and systems for producing and integrating optoelectronic devices.

### BACKGROUND

VCSELs (vertical-cavity surface-emitting lasers) are semiconductor lasers, wherein the highly directional laser radiation is emitted from the top or bottom of the laser in a direction perpendicular to the substrate. VCSELs are manufactured either as single lasers or as laser arrays, and they are capable of high emission powers.

### SUMMARY

An embodiment that is described herein provides an optoelectronic device includes: (i) a semiconductor substrate doped with a first level of n-type dopants, (ii) a contact semiconductor layer disposed over the semiconductor substrate and doped with a second level of n-type dopants, larger than the first level, (iii) an upper distributed Bragg-reflector (DBR) stack disposed over the contact semiconductor layer and including alternating first and second epitaxial semiconductor layers having respective first and second indexes of refraction that differ from one another in a predefined wavelength band, (iv) a set of epitaxial layers disposed over the upper DBR, the set of epitaxial layers includes one or more III-V semiconductor materials and defines: (a) a quantum well structure, and (b) a confinement layer, and (v) a lower DBR stack disposed over the set of epitaxial layers, opposite the upper DBR, and including alternating dielectric and semiconductor layers.

In some embodiments, the quantum well structure is configured to emit a light beam having a wavelength in the predefined wavelength band. In other embodiments, at least one of: (i) the semiconductor substrate, (ii) the contact semiconductor layer, and (iii) the set of epitaxial layers, includes indium-phosphide, and the emitted light beam has a wavelength between 1.2 μm and 2 μm. In yet other embodiments, at least one of: (i) the semiconductor substrate, (ii) the contact semiconductor layer, and (iii) the set of epitaxial layers, includes gallium-antimony, and the emitted light beam has a wavelength larger than 2 μm.

In an embodiment, at least one of: (i) the semiconductor substrate, (ii) the contact semiconductor layer, and (iii) the set of epitaxial layers, includes gallium-arsenide, and the emitted light beam has a wavelength between 0.63 μm and 1.1 μm. In another embodiment, at least one of: (i) the semiconductor substrate, (ii) the contact semiconductor layer, and (iii) the set of epitaxial layers, includes gallium-nitride, and the emitted light beam has a wavelength smaller than 0.6 μm. In yet another embodiment, the device includes electrodes, coupled to apply an excitation current to the quantum well structure.

In some embodiments, the electrodes include a first electrode and a second electrode, and the device further including (i) a first bump, electrically coupled between the first electrode and the contact semiconductor layer and (ii) a second bump coupled between the second electrode and an additional contact semiconductor layer, and the first and second bumps are configured to conduct the excitation current applied to the quantum well structure. In other embodiments, the lower DBR includes, in addition to the alternating dielectric and semiconductor layers, alternating third and fourth epitaxial semiconductor layers having respective third and fourth indexes of refraction that differ from one another in the predefined wavelength band.

In an embodiment, the quantum well structure is configured to detect light in the predefined wavelength. In another embodiment, the device includes electrodes, coupled to receive, from the quantum well structure, a signal indicative of the detected light beam.

An additional embodiment that is described herein provides a method for producing an optoelectronic device, the method includes disposing, over a semiconductor substrate doped with a first level of n-type dopants, a contact semiconductor layer and doping the contact semiconductor layer with a second level of n-type dopants, larger than the first level. An upper distributed Bragg-reflector (DBR) stack is disposed over the contact semiconductor layer. The upper DBR includes alternating first and second epitaxial semiconductor layers having respective first and second indexes of refraction that differ from one another in a predefined wavelength band. A set of epitaxial layers is disposed over the upper DBR, the set of epitaxial layers includes one or more III-V semiconductor materials, defining a quantum well structure, and a confinement layer. A lower DBR stack that includes alternating dielectric and semiconductor layers, is disposed over the set of epitaxial layers, opposite the upper DBR.

An additional embodiment that is described herein provides a method including, operating an optoelectronic device. The optoelectronic device includes: (i) a semiconductor substrate doped with a first level of n-type dopants, (ii) a contact semiconductor layer disposed over the semiconductor substrate and doped with a second level of n-type dopants, larger than the first level, (iii) an upper distributed Bragg-reflector (DBR) stack disposed over the contact semiconductor layer and includes alternating first and second epitaxial semiconductor layers having respective first and second indexes of refraction that differ from one another in a predefined wavelength band, (iv) a set of epitaxial layers disposed over the upper DBR, the set of epitaxial layers includes one or more III-V semiconductor materials and defines: (a) a quantum well structure, and (b) a confinement layer, and (v) a lower DBR stack disposed over the set of epitaxial layers, opposite the upper DBR, and including alternating dielectric and semiconductor layers. An excitation current is applied to the quantum well structure for emitting a light beam having a wavelength in the predefined wavelength band.

These and other embodiments will be more fully understood from the following detailed description of the embodiments thereof, taken together with the drawings in which:

### BRIEF DESCRIPTION OF THE DRAWINGS

FIG. 1 is a schematic sectional view of an integrated optoelectronic module (IOM), in accordance with an embodiment that is described herein; and

FIGS. 2-6 are schematic sectional views of a process sequence for producing an IOM, in accordance with an embodiment that is described herein.

### DETAILED DESCRIPTION OF EMBODIMENTS

### Overview

Vertical-cavity surface-emitting lasers (VCSELs) based on III-V semiconductor compounds are configured for emitting light beams in a predefine wavelength (WL) range. For example, indium phosphide (InP)-based VCSELs are configured to emit light beams in a WL-range between 1.2 μm and 2 μm. The InP-chips carrying the VCSELs can be bonded to a carrier substrate, such as a silicon (Si) substrate, in order to take advantage of the complementary metal-oxide semiconductor (CMOS) control circuits on a Si-wafer.

In the present example, the Si-wafer comprises a backplane driver having arrays of electrodes, also referred to herein as anodes and cathodes, which are configured to supply excitation current for selectively operating one or more InP VCSELs of the bonded InP-chip.

In the context of the present description and in the claims, the term “substrate” may refer either to a complete wafer or to a part of a wafer, such as in a semiconductor die or chip.

In some embodiments, InP-based VCSELs can be produced by depositing, on an n-type InP substrate, a stack of epitaxial layers using the following process sequence. At a first step, a heavily-doped n-type contact InP layer is disposed on the InP substrate. At a second step, an upper reflector, referred to herein as an upper distributed Bragg-reflector (DBR) stack, is disposed over the contact InP layer. The upper DBR comprises alternating first and second n-type epitaxial semiconductor layers (e.g., alternating AlGaInAs and InP layers with grading layer in between), also referred to herein as an nDBR. The first and second layers of the nDBR have respective first and second indexes of refraction that differ from one another in a predefined wavelength band. In this configuration, the upper reflector is configured to have a reflectivity exceeding 99% at the aforementioned WL-range.

At a third step, a set of epitaxial III-V semiconductor layers is disposed over the upper DBR, and defining a quantum well (QW) structure, and a lightly doped p-type semiconductor layer is deposited over the QW. The QW structure (including quantum well and barrier layers) is configured to emit light beams in the predefined wavelength band. In addition, electrical and optical confinement is disposed. The electrical and optical confinement, also referred to herein as a confinement layer (or multi-layered structure), can be achieved by, for example, buried tunnel junction (BTJ), or lateral oxidation, ion implantation or other techniques that are known in the art. Take BTJ as an example, semiconductor layers functioning as tunnel junction (TJ) is deposited over p-doped semiconductor layer.

In some embodiments, the TJ may comprise thin heavily p-doped semiconductor layers in conjunction with heavily n-doped semiconductor layers, forming TJ and providing a low electrical resistance. By placing the TJ at the optical standing wave node where light-wave intensity is nearly zero, low optical loss can be achieved. BTJ is formed by patterning and selective etching off TJ and landing on top to the p-type semiconductor layer, then depositing n-type semiconductor layer over the TJ. BTJ enables electrical and optical confinement. Under forward electrical bias across the BTJ, electrical current flow will only flow within the BTJ aperture, and be blocked outside the aperture due to reverse biased p-n junction, hence electrical confinement is formed. Due to effective optical index contrast within and outside the BTJ aperture, optical field is laterally confined within the BTJ aperture.

Subsequently, a lower reflector, also referred to herein as a lower DBR stack, is disposed over the set of epitaxial layers. Note that the upper DBR is disposed over a first side of the set of epitaxial III-V semiconductor layers, and the lower DBR is disposed over a second side thereof, opposite the first side.

In some embodiments, the lower DBR comprises repetitive pairs (e.g., about 5 or 6 pairs) of high- and low-index alternating layers. In the present example, the alternating layers comprising dielectric (e.g., silicon-oxide and amorphous silicon) materials, so that this structure is referred to herein as a dielectric DBR (DD). In this configuration the DD is configured to have a reflectivity exceeding 99.9% at the aforementioned WL-range.

In other embodiments, the lower DBR may comprise an nDBR (having a few pairs of alternating n-type epitaxial semiconductor layers) disposed over the set of epitaxial III-V semiconductor layers, and a few pairs of the DD layers disposed over the nDBR. Such combination of dielectric DBR and nDBR in a single reflector is also referred to herein as a hybrid reflector. In some cases, the thickness of the alternating DD layers (e.g., about a quarter of the local wavelength of the light emitted by the InP VCSEL) may not be sufficiently accurate. In such cases, the combination of DD and nDBR in the hybrid deflector, may improve the uniformity of the WL reflected from the lower reflector, while retaining reflection exceeding 99% at the aforementioned WL-range of the InP-based VCSEL.

Good thermal conductivity between the VCSEL and the substrate is important in order to dissipate the heat generated by the VCSEL excitation current. The thermal conductivity may suffer based on the choice of the materials and thicknesses of the upper and lower reflectors and other layers at the VCSEL/substrate interface.

Optimizing the performance of InP-based VCSELs calls for a high degree of both electrical and optical confinement, as well good thermal conductivity from the VCSEL to the silicon and InP substrates. In some embodiments, the InP substrate serves as a thermal mass for reducing the temperature of the QW structure and TJ or BTJ of the VCSEL. The embodiments of the present invention that are described herein address these needs so as to enable the fabrication of InP-based VCSELs with high output power and high efficiency, as well as good optical mode confinement.

In some embodiments, metal layers (e.g., traces and vias) are deposited and patterned onto and through the epitaxial layers so as to apply an excitation current to the quantum well structure. In some embodiments, in order to enhance heat removal from the active region, one or both of the metal layers comprise rings, also referred to herein as mesa, disposed in close proximity to and surrounding the quantum well structure. The metal vias pass through one or both of the DBR stacks so as to connect the metal ring at the inner side of the DBR stack to an electrical contact on the outer side of the DBR stack. As described above, a chip comprising the VCSELs is bonded to the Si-wafer, and a passivation layer is disposed therebetween for improving the mechanical, electrical and environmental (e.g., moisture) stability of a VCSEL-based integrated optoelectronic module.

In other embodiments, instead of producing a VCSEL, the production method described above may be used, mutatis mutandis, for producing a resonant-cavity photodetector-on-silicon (RCPD-on-Si), for example, by reducing the number of nDBR pairs in the upper reflector.

Although the disclosed embodiments use an InP substrate and an epitaxial stack based on InP, other III-V semiconductor materials and/or compounds, such as but not limited to gallium-arsenide (GaAs), gallium-antimony (GaSb), gallium-nitride (GaN), indium-arsenide (InAs), may alternatively be used at least for the substrate and the epitaxial stack. In some embodiments, the GaAs-based, GaSb-based, InAs-based, and GaN-based VCSELs may be used for producing light beams in wider spectral coverage. For example, a GaSb-based VCSEL is configured to emit a WL of about 2 μm or longer, and a GaN-based VCSEL is configured to emit a WL of about 0.6 μm and shorter.

### System Description

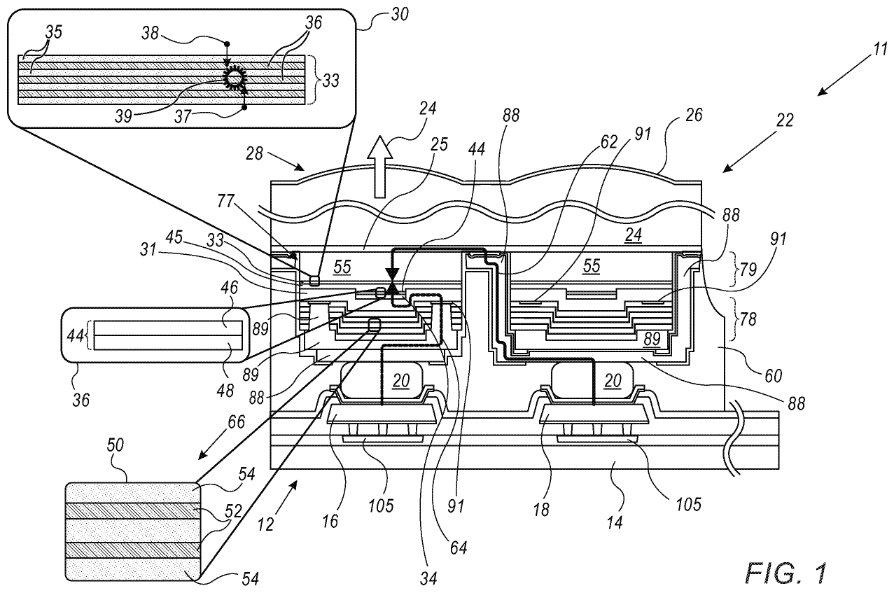

FIG. 1 is a schematic sectional view of an integrated optoelectronic module (IOM), referred to herein as a module 11, in accordance with an embodiment that is described herein. In some embodiments, module 11 comprises a light source, in the present example a vertical-cavity surface-emitting laser (VCSEL) device (VD) 22 and a backplane driver, in the present example a backplane silicon driver (BSD) 12.

In some embodiments, BSD 12 comprises multiple electrodes, referred to herein as anodes 16 and cathodes 18, produced on a silicon wafer 14 (or any other suitable type of substrate) using any suitable Complementary Metal Oxide Semiconductor (CMOS) processes. In some embodiments, pairs of anodes 16 and cathodes 18 are arranged in arrays across BSD 12.

In some embodiments, BSD 12 comprises electrical traces 105 configured to conduct electrical current between a power source and various components of BSD 12, such as anodes 16 and cathodes 18. In such embodiments, based on the routing of electrical traces 105, BSD 12 is configured to conduct the electrical current to or from selected one or more pairs of anodes 16 and cathodes 18.

In some embodiments, BSD 12 is configured to supply power to VD 22 for emitting, from VD 22 of module 11, a light beam 32 having a predefined wavelength (WL), as will be described in detail below. In the context of the present description and in the claims, the terms “optical radiation,” “light beam,” “light” and “beam” are used interchangeably and refer generally to any and all of visible, infrared, and ultraviolet radiation.

### Indium Phosphide-Based VCSEL Integrated on Silicon for Emitting WL-Range Between About 1.2 μM and 2 μM

In some embodiments, VD 22 comprises a set of epitaxial layers comprising one or more III-V semiconductor materials and defining (i) one or more light-producing stacks of layers comprising, inter-alia, a quantum well (QW) structure described in detail below, and (ii) one or more confinement layers.

In some embodiments, VD 22 comprises a multi-layered structure comprising an active region (AR) 33 (described in detail in an inset 30 below), a lightly p-doped semiconductor layer (e.g., indium-phosphide (InP), indium-gallium-arsenide-phosphide (InGaAsP), or aluminum-indium-gallium-arsenide (AlInGaAs), aluminum-gallium-arsenide-antimony (AlGaAsSb)), referred to herein as a layer 45, and a buried tunnel junction (TJ) 44 (described in detail in an inset 36 below).

Advanced VCSELs, such as VD 22, employ methods and structures to confine both the electrical current and the optical radiation within VD 22. Confinement of the electrical current brings the carriers into a well-defined volume within the central area in a multi-layered quantum well (QW) stack of VD 22, and the optical confinement controls the spatial modes of the optical radiation generated by VD 22. The QW stack is described in detail in inset 30 below. One method for confining the electrical current in InP-based VCSELs comprises implanting ions in areas around a desired current path. Another method uses BTJ, it contains a laterally-etched TJ covered with epitaxial regrown n-doped semiconductor layer for both optical and electrical confinement. In the present example, the confinement structure is implemented in VD 22 using a tunnel junction (TJ) structure described herein.

Reference is now made to inset 36. In some embodiments, TJ 44 may comprise homogeneous or heterogeneous types of tunnel junction (TJ). In the example of FIG. 1, TJ 44 comprises a heterogeneous type of TJ, comprising a stack of two heavily doped semiconductor layers. For example, (i) a layer 48 comprising aluminum-gallium-arsenide-antimony (AlGaAsSb), or any other suitable substance or compound, heavily-doped with p-type ions, and (ii) a layer 46 comprising indium-gallium-arsenide-phosphide (InGaAsP), or aluminum-indium-gallium-arsenide (AlInGaAs), each of which heavily-doped with n- type ions.

In other embodiments, instead of TJ 44, the confinement structure may be implemented in VD 22 by forming an oxide aperture filled with a layer formed by an atomic layer deposition (ALD) process, or by doping a semiconductor layer using a suitable ion implanting process.

In the context of the embodiments described herein and in the claims, the term “heavily doped” refers to an n-type or a p-type carrier concentration that may range about or above 1×10¹⁹ cm⁻³ or any other suitable doping level, and the term “doped” refers to an n-type or a p-type carrier concentration that may range between about 10¹⁵ cm⁻³ and 10¹⁹ cm⁻³ or any other suitable doping level. Note that the doping level may be substantially different, (a) for different substances receiving the dopant, and (b) based on the specified optical and/or electrical property (e.g., conductivity, mobility, refractive index) of the substance receiving the dopant.

In the context of the embodiments described herein and in the claims, the terms “about” or “approximately” for any numerical values or ranges indicate a suitable dimensional tolerance that allows the part or collection of components to function for its intended purpose as described herein. More specifically, “about” or “approximately” may refer to the range of values ±20% of the recited value, e.g. “about 90%” may refer to the range of values from 71% to 99%. Reference is now made to inset 30 showing a single junction of AR 33. In some embodiments, each junction comprises multiple pairs (e.g., between 3 and 7 pairs) of alternating quantum well (QW) layers 36 and barrier layers 35. In some embodiments, QW layers 36 comprising any suitable substance, such as but not limited to InₓGa₁₋ₓAs, InₓAl_{y}Ga_{1-x-y}As, InₓGa₁₋ₓAs_{y}P_{1-y} and/or InₓGa₁₋ₓAs_{y}N_{1-y}. In some embodiments, barrier layers 35 are alternately situated between adjacent QW layers 36 as shown in inset 30. Each barrier layer 35 may comprise InP, AlₓGa₁₋ₓAs_{y}Sb_{1-y}, InₐAl₁₋ₐAs, InₐAl_{b}Ga_{1-a-b}As, InₐGa₁₋ₐAs_{b}P_{1-b} and/or InₐGa₁₋ₐAs_{b}N_{1-b} or any other suitable type of barrier materials. In some embodiments, the typical thickness of each QW layer 36 and barrier layer 35 is in the nanometer range (e.g., between 1 and 15 nm).

Reference is now made back to the general view of FIG. 1. When module 11 is powered, electrical current, also referred to herein as an excitation current, is conducted between BSD 12 and a light-producing stack of layers (e.g., AR 33, layer 45 and TJ 44) via conductivity paths, referred to herein as current paths 62 and 64 described in detail below. Reference is now made back to inset 30. In some embodiments, the excitation current applied to the QW layers of AR 33, causes a recombination 39 between an electron 37 and a hole 38 resulting in emission of light beam 32.

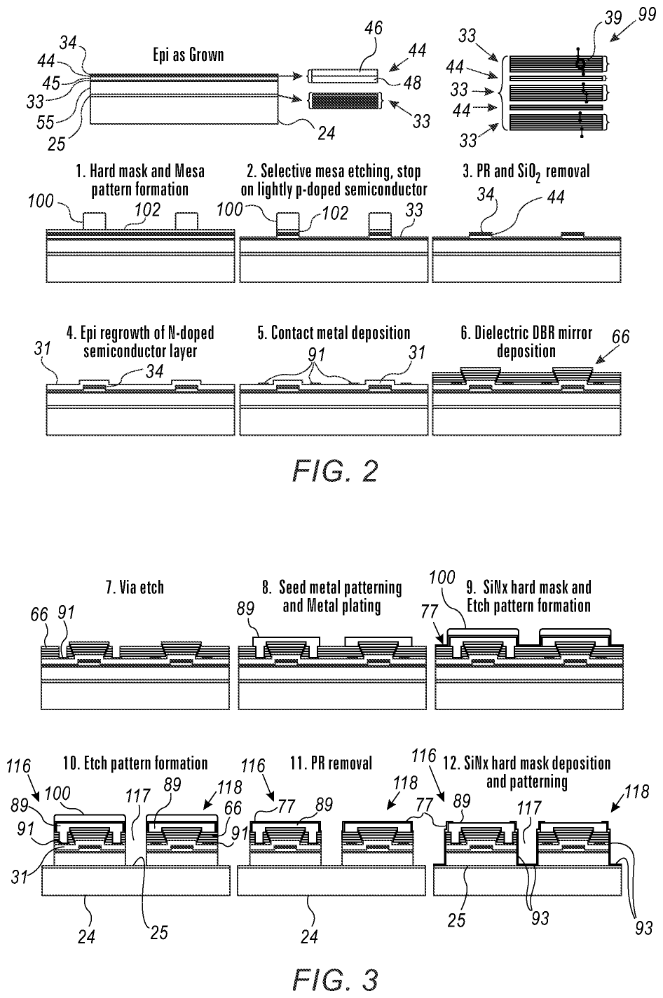

In other embodiments, AR 33 may comprise multiple junctions having a TJ 44 laid out between adjacent junctions of AR 33, this configuration is shown and described in detail in FIG. 2 below.

Reference is now made back to the general view of FIG. 1. In some embodiments, VD 22 comprises a distributed Bragg reflector (DBR) stack, referred to herein as a lower DBR 78, which is positioned between TJ 44 and one or more layers 88 of metal. Lower DBR 78 is configured to reflect light beam 32 emitted from AR 33, to a lens 28 and/or to any other suitable optical assembly, so as to direct light beam 32 to a target scene out of VD 22.

In some embodiments, lower DBR 78 comprise one or more types of DBR stacks, referred to herein as (i) a dielectric DBR (DD) 66, and (ii) a semiconductor epitaxial n-type DBR (nDBR), in the present example, a layer 31 (and possibly also layer 34) also referred to herein as nDBR. Embodiments related to nDBR are described in detail below.

In some embodiments, DD 66 comprises repetitive pairs of high- and low-index materials, wherein the thickness of each layer is a quarter of the local wavelength of the light emitted by AR 33 (i.e., the free-space wavelength divided by the index of refraction of the material at the wavelength).

Reference is now made to an inset 50, showing the structure of DD 66. In some embodiments, DD 66 comprises a stack of multiple (e.g., about 5 or 6) pairs of alternating layers 52 and 54 having refractive indexes substantially different from one another. For example, DD 66 may comprise pairs of amorphous silicon and silicon dioxide (a-Si/SiO₂), amorphous silicon and aluminum nitride (a-Si/AlN), amorphous silicon and aluminum oxide (a-Si/Al₂O₃), or any other suitable pair of layers.

In some embodiments, the geometrical size of layers 52 and 54, and the difference in the refractive indexes thereof, are resulting in a high index contrast DBR. In such embodiments, the stack of DD 66 is designed to have a reflectivity exceeding 99.9% at the WL of light beam 32.

Dielectric DBRs are described in detail, for example, in PCT Patent Application PCT/US2020/18475, whose disclosure is incorporated herein by reference.

Reference is now made back to the general view of FIG. 1. In some embodiments, VD 22 comprises an upper DBR 79 having alternating high- and low-index n-type layers (not shown) epitaxially grown to define an epitaxial n-type DBR, referred to herein as an ED 55. In such embodiments, ED 55 may have a high index contrast (e.g., Δn>0.35) by selecting combinations of material and/or compounds used in nDBRs, some nDBR material combination can be, but not limit to:

(a) AlₓGa₁₋ₓAs_{y}Sb_{1-y} wherein x<0.3, and AlₓGa₁₋ₓAs_{y}Sb_{1-y} wherein x>0.8; or

(b) InGaAs and indium-aluminum-arsenide (InAlAs); or

(c) Aluminum-gallium-indium-arsenide (AlGaInAs) and indium-phosphide (InP).

In other embodiments, the aforementioned nDBR may be obtained by selecting compounds with direct bandgap for low and high index layer as well as grading layers, defining a so-called direct-bandgap nDBR. In such embodiments, ED 55 may comprise a combination of material and/or compounds such as:

AlₓGa₁₋ₓAs_{y}S_{1-y} wherein x<0.3 as high index layer, and InP as low index layer, with a direct-bandgap grading layer (such as AlInAs, AlInAsSb, AlInAsP, GaPSb, GaAsSb, AlGaPSb) for obtaining high optical index contrast with improved resistivity, e.g., lower resistivity compared to the (a) (b) and (c) combinations described above.

The inventors believe that the root cause of the increased resistance is scattering of electrons between the valleys of the conduction bands of the crystal lattice in the successive layers of the nDBR. The electron scattering can be mitigated if the different compositions of the semiconductor compounds making up all of the layers of the nDBR are chosen so that the compounds have direct bandgaps.

In the context of the present description and in the claims, a “direct-bandgap” semiconductor material is one in which the F-valley in the energy-momentum (E-k) curve is the point of lowest energy in the conduction band (lower than the X- and L-valleys). In comparison, an “indirect-bandgap” semiconductor material is one in which the F-valley in the E-k curve is not the point of lowest energy in the conduction band (but rather has higher energy than the X- and/or L-valley).

Various sorts of nDBRs and direct-bandgap nDBRs are described in detail, for example, in U.S. Provisional Applications 62/892,613 filed 28 Aug. 2019, and 62/958,732 filed 9 Jan. 2020, whose disclosures are all incorporated herein by reference.

In some embodiments, by using the combinations of compounds and/or the direct-bandgap nDBR described above, ED 55 of upper DBR 79 may obtain the aforementioned index contrast of Δn>0.35. In such embodiments, an nDBR having less than 25 pairs of layers may obtain reflectivity exceeding 99% at the WL of light beam 32.

Typically, III-V semiconductor alloys have relatively low thermal conductivity, for example, the thermal conductivity of InP is about 0.68 W cm⁻¹ ° C.⁻¹, and the thermal conductivity of the aforementioned nDBR structure is reduced with the thickness of such compounds. InP-based VCSELs known in the art (also referred to herein as conventional InP-based VCSELs) use more than 45 pairs of nDBR layers as end mirror reflector to obtain reflectivity exceeding about 99.99% at the WL of light beam 32. Such large number of pairs of nDBR layers limits effective thermal dissipation from active region to a heat sink (not shown) of module 11. In the example of VD 22, the inventors may use nDBR for a transmission side mirror, which is required to have a reflectivity exceeding 99% at the WL of light beam 32 (smaller than reflectivity exceeding 99.9% at the same WL, which is required from an end mirror reflector). In this configuration, an nDBR having less than 25 pairs of layers is sufficient for meeting the required reflectivity of a transmission side mirror. Moreover, in this configuration the thermal resistance of the nDBR of the present disclosure is substantially smaller than that of a conventional InP-based VCSEL, and is therefore referred to herein as “affordable thermal resistance.”

In some embodiments, lower DBR 78 may comprise only DD 66. Alternatively, lower DBR 78 may comprise a hybrid reflector having a combination of DD 66 and a few pairs of nDBR layers. In the present example, layer 31 comprises the nDBR layers. Alternatively, the hybrid reflector may comprise any suitable combination of DD 66 with any suitable sort of one or more n-type semiconductor layers.

In some cases, an insufficient thickness uniformity of layers 52 and 54 may affect (e.g., reduce) the WL uniformity of light beam 32 reflected from DD 66. In some embodiments, the aforementioned combination of DD 66 and nDBRs may compensate for insufficient thickness uniformity of layers 52 and 54, so as to improve the WL uniformity of light beam 32.

In some embodiments, VD 22 comprises a semi-insulating (SI) substrate, typically made from a III-V semiconductor compound, and referred to herein as a substrate 24, and a contact layer, referred to herein as a layer 25 deposited on substrate 24. In some embodiments, substrate 24 provides thermal mass for reducing the temperature in TJ 44, AR 33 and other layers of VD 22. Substrate 24 is further configured to reduce the absorption of charge carriers in VD 22, and therefore, improve the efficiency of module 11. In other words, by using the same input power and reducing the amount of absorbed carriers, VD 22 is configured to (a) emit larger intensity of light beam 32, and (b) reduce the level of heat induced during the operation of module 11.

In some embodiments, VCSEL wavelength may be determined based on (i) the layers and structure of AR 33, and (ii) the resonance WL of the cavity as described herein. The composition, thickness and number of layers 35 and 36 of AR 33, determines what wavelength range of light beam can be emitted from AR 33 through electron-hole recombination. The cavity resonance wavelength is determined based on the refractive index, absorption loss and thickness of the aforementioned layers of VD 22, such as ED 55, AR 33, layer 45, TJ 44, layer 31, layer 34, DD 66, substrate 24, layer 25, and even a metallic layer 89. The cavity resonance wavelength has to be within the spectrum emitted from AR 33, so as to obtain the VCSEL operation. Once this requirement is met, the WL emitted from the VCSEL is determined by the cavity resonance WL.

For VCSEL grown on InP substrate (referred to as InP-based VCSEL), the emitted WL is within a range between about 1.2 um to 2 um.

In some embodiments, module 11 comprises bumps 20 (e.g., metal bumps, solder bumps or any other suitable type of bumps) formed on pairs of electrodes, also referred to herein as an anode 16 and a cathode 18 using any suitable process. Module 11 further comprises layers 88, and 89 typically comprising metal, such as aluminum, or copper, or suitable alloys thereof, or any other suitable substance or alloy.

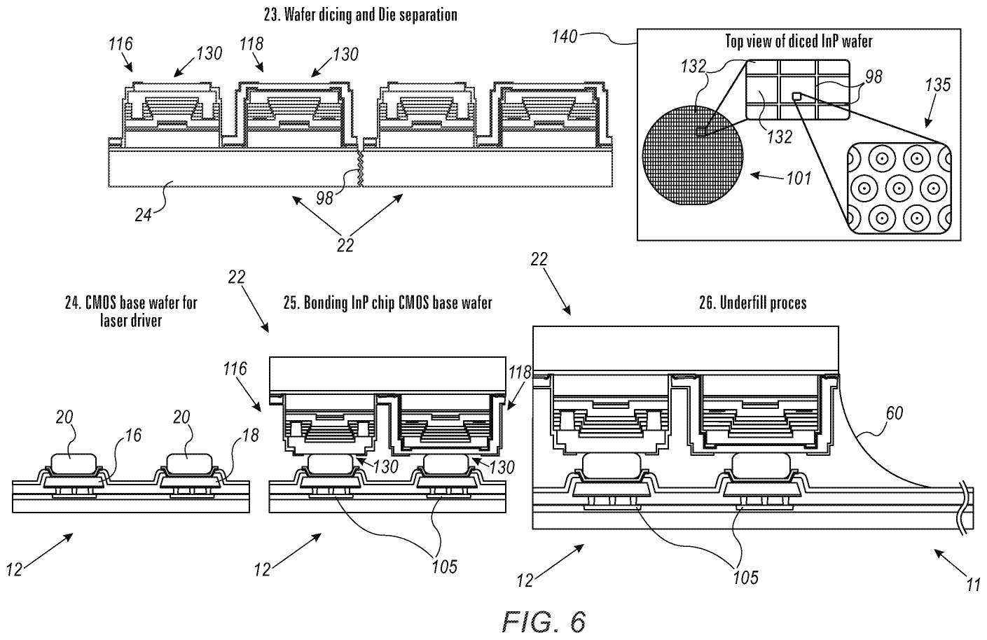

In some embodiments, an InP wafer (shown and described in FIG. 6 below) comprises multiple dies produced on substrate 24. After producing the dies, the InP wafer is diced and separated into individual InP chips, each of the InP chips comprising one or more VDs 22. The process for producing VDs 22 is described in detail in FIGS. 2-6 below.

In some embodiments, after producing VDs 22, each InP chip having one or more VDs 22, is placed on BSD 12. As shown in FIG. 1, each VD 22 is bonded to a pair of bumps 20 formed on a respective pair of anode 16 and cathode 18, so that each VD 22 is powered selectively by applying the aforementioned power to a selected pair of anode 16 and cathode 18 of BSD 12. This configuration enables a tight package of an array of light emitters (e.g., VCSEL devices 22) and individually addressing and operating each VCSEL emitter.

In some embodiments, an InP-based VCSEL array may have multiple optional configurations, such as but not limited to: (i) each VCSEL emitter has a respective anode 16 and all the VCSEL emitters share one or more common cathodes 18, this configuration is referred to herein as a common-cathode configuration, (ii) similarly, the array may have a common-anode configuration, and (iii) each emitter has a respective pair of anode 16 and cathode 18.

In some embodiments, the excitation current is conducted in current path 64 between anode 16 and the aforementioned light-producing stack of layers (e.g., AR 33, layer 45 and TJ 44), via bump 20 and layers 88, 89, 31 and 34. The excitation current is also conducted in current path 62 between cathode 18 and the light-producing stack of layers, via bump 20 and layers 88 and 25. Note that, due to the high doping level therein, the conductivity of layer 25 is sufficiently-high for conducting current path 62.

In some embodiments, in order to enhance heat removal from the light-producing stack of layers, some metal layers such as contacts 91, comprise rings (also shown as mesa features in FIG. 6 below) disposed in close proximity to the QW structure. In the example of FIG. 1, layer 89 passes through one or both of the DBR stacks (e.g., DD 66), so as to connect the metal ring at the inner side of the DBR stack to an electrical contact on the outer side of the DBR stack.

In some embodiments, layers 88 and 89 may constitute intra-cavity contact with plated metal via, so as to serve as heat sinks for dissipating the heat produced in the light-producing stack of layers.

In some embodiments, VD 22 comprises an anti-reflective (AR) layer 26, which is formed on substrate 24 (e.g., after a thinning process of substrate 24). AR layer 26 is configured to prevent reflection of light beam 32 from the interface between substrate 24 surface and air, back into VD 22. Such optical reflection back to the cavity of VD 22 may undesirably interfere with the specified gain and other performance of VD 22, and may undesirably increase the heat within VD 22 and module 11.

In some embodiments, VD 22 further comprises a filler 60, also referred to herein as “underfill,” which is typically made from suitable polymers and is configured to provide module 11 with improved mechanical stability, heat dissipation, and electrical isolation between some adjacent conductive components.

In some embodiments, VD 22 comprises passivation layers 77, which are typically comprising compounds such as silicon-nitride (SiNₓ) or other compounds that are known in the art, and are configured to physically and electrically isolate between adjacent layers. For example, to prevent undesired diffusion and/or electrical leaks between adjacent layers.

In some embodiments, in addition to, or instead of lens 28, VD 22 may have other optical elements, such as micro-lens or diffractive optical elements (DOEs) that may be integrated with substrate 24 (e.g., on top of substrate 24) so as to obtain shaping and/or steering and/or any other manipulation of light beam 32.

### Controlling the Wavelength Emitted From a Predefined VCSEL Structure by Selecting Different Materials

In some embodiments, the structure of VD 22 described above may be used for producing various types of VCSELs that are integrated on silicon, such as BSD 12, and are configured to emit different respective wavelengths.

### Gallium Antimony-Based VCSEL Integrated on Silicon for Emitting WL Larger Than 2 μM

In some embodiments, the structure of VD 22 may be used for producing a gallium-antimony (GaSb)-based VCSEL, which is configured to emit light beam 32 at a WL larger than about 2 μm. In such embodiments, substrate 24 and layer 25 may comprise semi-insulating or n-doped GaSb substrate, and the heavily-doped GaSb layer 25 is configured for forming ohmic contact with metallic layer 96 to conduct electrical current with low electrical resistance.

In some embodiments, ED 55 may comprise combinations of material and/or compounds of nDBR, such as:

(a) GaSb and AlAsSb , or InGaAsSb and AlAsSb, or GaSb and AlPSb, or other suitable combinations of material and/or compounds as respective high and low refractive index layer together with grading layer in between, or

(b) Direct bandgap nDBR such as: InGaAsSb and AlGaAsSb as high and low refractive index layer together with direct bandgap grading layers. This configuration may have lower resistivity relative to the combination (a). In such embodiments, an nDBR having less than 25 pairs of layers may obtain reflectivity exceeding 99% at the WL of light beam 32 and affordable thermal resistance as described above for the InP-based VCSEL.

In some embodiments, TJ 44 of the GaSb-based VCSEL may have a heterogeneous structure comprising heavily-doped p-type GaSb in layer 48, and heavily-doped n-type InAsSb in layer 46. In some embodiments, AR 33 may comprise a single junction or a multi-junction (having TJs 44 between each pair of adjacent junctions, as will be described in FIG. 2 below). Each junction may comprise between about 3 and 7 pairs of layers 35 and 36. For example, each layer 36 may comprise InGaAsSb QW configured to emit WL larger than about 2 μm, and each barrier layer 35 may comprise AlGaAsSb.

### Gallium Arsenide-Based VCSEL Integrated on Silicon for Emitting WL-Range Between About 0.63 μm and 1.1 μm

In some embodiments, the structure of VD 22 may be used for producing a gallium-arsenide (GaAs)-based VCSEL, which is configured to emit light beam 32 within a WL-range between about 0.63 μm and 1.1 μm. In such embodiments, substrate 24 may comprise n-doped or semi-insulating GaAs substrate. Layer 25 may comprise heavily n-doped GaAs, is configured forming ohmic contact with metallic layer 96 to conduct electrical current with low resistance.

In alternative embodiments, by using in AR 33 diluted nitride (DN) QW layers (e.g., InGaAsN and InGaAsNSb), the WL of light beam 32 emitted from VD 22 may be extended to a WL-range between about 1 μm and 1.6 μm.

In some embodiments, ED 55 may have the aforementioned index contrast (e.g., Δn>0.35) by selecting combinations of material and/or compounds of nDBR, such as:

(a) AlₓGa₁₋ₓAs wherein 0≤x<0.3, and AlₓGa₁₋ₓAs wherein 0.7≤x≤1 as respective high and low refractive index layer, together with grading layer in between each high and low index layer; or

(b) Direct bandgap nDBR such as:

GaAs and AlₓGa_{y}In_{1-x-y}P wherein x<0.35 as direct bandgap layer with respective high and low refractive index, together with direct bandgap grading layer such as InGaP and InₓGa₁₋ₓAs_{y}P_{1-y}, and therefore, having lower resistivity as compared with (a).

In such embodiments, an nDBR having less than 25 pairs of layers may obtain reflectivity exceeding 99% at the aforementioned WL-range of light beam 32, and affordable thermal resistance as described above for the InP-based VCSEL.

In some embodiments, DD 66 of the GaAs-based VCSEL may comprise pairs of amorphous-silicon and silicon dioxide (a-Si/SiO₂), amorphous-silicon and aluminum nitride (a-Si/AlN), amorphous-silicon and aluminum oxide (a-Si/Al₂O₃), amorphous-silicon and beryllium oxide (a-Si/BeO), or any other suitable pair of layers. In such embodiments, the stack of DD 66 is designed to have about 5 or 6 pairs of the layers described above. In these configurations, DD 66 is configured to obtain a reflectivity exceeding 99.9% at a WL-range between about 0.9 μm and 1.6 μm of light beam 32.

When the GaAs-based VCSEL is designed to emit a WL-range between about 0.63 μm and 0.9 μm, an amorphous-silicon layer in DD 66 may cause high absorption of light beam 32, and thereby undesirably reducing the reflectivity of DD 66. In some embodiments, DD 66 of the GaAs-based VCSEL designed to emit WL-range between about 0.63 μm and 0.9 μm, may have pairs of titanium-oxide (TiO₂) and silicon-dioxide (SiO₂) layers or any other suitable compounds. In such embodiments, DD 66 may comprise ten or more pairs of these layers so as to obtain a reflectivity exceeding 99.9% at the WL-range between about 0.63 μm and 0.9 μm of light beam 32.

In some embodiments, TJ 44 may comprise homogeneous or heterogeneous tunnel junction. An example of heterogeneous TJ 44 may comprise layer 46 using heavily-doped n-type InGaAsN and layer 48 using heavily-doped p-type InGaAs.

In some embodiments, the QW structure of AR 33 may comprise a single junction or a multi-junction (having TJs 44 between each pair of adjacent junctions). Each junction may comprise between about 3 and 7 pairs of layers 35 and 36, and configured to emit light beam 32 having any of the aforementioned WL-ranges. For example, each layer 36 may comprise suitable types of QW layers, such as but not limited to GaAs, InₓGa₁₋ₓAs, InₓGa₁₋ₓP, InGaAsN, or InGaAsNSb, and each barrier layer 35 may comprise layers such as not limited to GaAs, AlₓGa₁₋ₓAs, GaAsₓP₁₋ₓ, AlₓGa_{y}In_{1-x-y}P.

In some embodiments, for the GaAs-based VCSEL, the other elements and layers of module 11 (e.g., the intra-cavity contact, BSD 12, and the optical elements) are similar to the corresponding elements and layers described above, for example, in the InP-based and GaSb-based VCSELs.

### Gallium Nitride-Based VCSEL Integrated on Silicon for Emitting WL Smaller Than 0.6 μm

In some embodiments, the structure of VD 22 may be used for producing a gallium-nitride (GaN)-based VCSEL, which is configured to emit light beam 32 at a WL smaller than about 0.6 μm. In such embodiments, substrate 24 may comprise n-doped or semi-insulating GaN substrate. Layer 25 may comprise heavily doped GaN layer, forming ohmic contact with metallic layer 96 to conduct electrical current with low electrical resistance.

In some embodiments, ED 55 may comprise selecting combinations of material and/or compounds of nDBR, such as: AlₓIn₁₋ₓN wherein x equals about 0.82 as low refractive index layer, and GaN as high refractive index layer, together with grading layer (such as AlₓGa_{y}In_{1-x-y}N) in between.

In such embodiments, an nDBR having less than 35 pairs of layers may obtain reflectivity exceeding 99% at the specified WL of light beam 32.

In some embodiments, DD 66 of the GaN-based VCSEL designed to emit WL smaller than about 0.6 μm, may have pairs of titanium-oxide (TiO₂) or Niobium-pentoxide (Nb₂O₅) or any other suitable compounds as high refractive index layer and silicon-dioxide (SiO₂) layers or any other suitable compounds as low refractive index layer. In such embodiments, DD 66 may comprise eight or more pairs of these layers so as to obtain a reflectivity exceeding 99.9% at WLs of light beam 32 that are smaller than about 0.6 μm.

In some embodiments, TJ 44 may comprise homogeneous or heterogeneous TJ. For homogeneous TJ, layer 46 may comprise heavily-doped n-type GaN and layer 48 may comprise heavily-doped p-type GaN, or any other suitable type of compounds.

In some embodiments, AR 33 may comprise a single junction or a multi-junction (having TJs 44 between each pair of adjacent junctions). Each junction may comprise between about 3 and 7 pairs of layers 35 and 36. For example, each layer 36 may comprise suitable types of QW layers, such as but not limited to InGaN, which are configured to emit light beam 32 having a WL smaller than 0.6 μm, and each barrier layer 35 may comprise GaN.

In some embodiments, for the GaN-based VCSEL, the other elements and layers of module 11 (e.g., the intra-cavity contact, BSD 12, and the optical elements) are similar to the corresponding elements and layers described above, for example, in the InP-based, GaSb-based, and GaAs-based VCSELs.

### Devices Other Than VCSEL Integrated With Silicon for Emitting Or Detecting a Predefined Range of Wavelengths

In some embodiments, instead of the VCSEL devices of VD 22 described above, module 11 may comprise any other suitable type of a light detection device, such as but not limited to a resonant-cavity photodetector-on-silicon (RCPD-on-Si). The RCPD-on-Si is configured to detect a light beam, at least in a predefined WL or a predefined range of WLs, and to produce a signal indicative of the detected light beam. In some embodiments, anode 16 and cathode 18 are configured to reverse biased (higher voltage at cathode than anode) to receive and conduct the signal to any suitable processor, via electrical traces 105. In such embodiments, a process (described in FIGS. 2-6 below) for producing module 11 having VD 22 may be used, mutatis mutandis, for producing module 11 having the RCPD-on-Si or any other suitable device. For example, the RCPD-on-Si may be formed by reducing the number of epitaxial nDBR layers in close proximity to substrate 24. In addition, optical and electrical confinement is not required in RCPD, hence layers 44, 34 and 31 may not be needed. Instead, additional p-doped semiconductor layer can be incorporated as anode metal contact layer. This configuration may obtain an array of RCPD having a tight design rule (e.g., a pitch of as small as about 5 μm).

Note that lens 28 or the like, or other suitable optical elements may also be used in conjunction with the aforementioned RCPD-on-Si devices for collecting the light beam detected by the RCPD.

Additional sorts of optoelectronic devices having VCSELs integrated on silicon control backplane, and production methods thereof, are described in detail, for example, in PCT Patent Publication WO 96/05768, whose disclosure is incorporated herein by reference.

In alternative embodiments, other semiconductor carrier substrates may be used, for BSD 12, instead of a 12″ silicon wafer of substrate 14. However, silicon has the benefit that, based on a well-established process technology, CMOS-circuits with very tight design rules (small lateral dimensions) may be manufactured with a high yield on the surface of the substrate and coupled to drive the VCSELs. This particular configuration of module 11 is shown by way of example, in order to illustrate certain problems that are addressed by embodiments of the present invention and to demonstrate the application of these embodiments in enhancing the performance of such a VCSEL-based module. Embodiments of the present invention, however, are by no means limited to this specific sort of example module, and the principles described herein may similarly be applied to other sorts of lasers or to other sorts of light emitting modules.

### Process Sequence for Producing VCSEL-on-Silicon

FIG. 2 is a diagram that schematically illustrates a sectional view of a process sequence for producing VCSEL-on-Silicon, such as module 11, in accordance with an embodiment that is described herein. In some embodiments, the process sequence of FIG. 2 described the formation of the light-producing stack of layers (comprising AR 33, layer 45 and TJ 44) and both upper DBR 79 and lower DBR 78.

In some embodiments, the process of FIGS. 2-6 below describes a process for producing an InP-based VCSEL-on-Silicon shown, for example, as VD 22 and BSD 12 of FIG. 1 above. However, the process of FIGS. 2-6 below may be used, mutatis mutandis, for producing any other suitable VCSELs, such as but not limited to the InP-based, GaSb-based, GaAs-based, and GaN-based VCSELs described in FIG. 1 above. The process of FIGS. 2-6 below may also be used, mutatis mutandis, for producing other devices, such as but not limited to the aforementioned RCPD-on-Si and any other suitable type of device formed on a silicon backplane, such as BSD 12.

The process begins with producing or receiving substrate 24 having a stack of epitaxial layers, such as layer 25, ED 55, AR 33, layer 45, TJ 44 and layer 34. Note that in the production process of FIGS. 2-6, substrate 24 and the stacked epitaxial layers are flipped (up-side-down) relative to FIG. 1 above. Moreover, the stack of epitaxial layers comprises ED 55 that also constitutes upper DBR 79, as described in FIG. 1 above.

In some embodiments, the light-producing stack of layers described in FIG. 1, may comprise a single stack of AR 33, layer 45 and TJ 44, this single stack is also referred to herein as a single junction.

In other embodiments, VD 22 may comprise the single stack repeated multiple times in a larger stack, referred to herein as a multi-junction (MJ) 99 active region. In the example, of FIG. 2 MJ 99 comprises a triple-junction stack having (i) three stacks of AR 33, (ii) two TJ 44, and (iii) four layers 45 with alternated n-type and p-type doping laid out between each AR 33 and TJ 44.

In this configuration, in response to power applied by BSD 12, resulting in the recombination process (shown as recombination 39) described in FIG. 1 above, VD 22 is configured to emit light beam 32 from each junction. Note that each TJ 44 is configured to form an ohmic electrical connection between the n-doped and p-doped layers laid out at the respective sides of each junction, so as to electrically connect between adjacent junctions.

In some embodiments, the process described in FIGS. 2-6 is carried out using any suitable III-V semiconductor fabrication processes, such as but not limited to: (a) thin-film (TF) deposition using chemical vapor deposition (CVD), metalorganic CVD (MOCVD), physical vapor deposition (PVD) also referred to herein as sputtering, electroplating (EP) and electrochemical plating (ECP) and atomic layer deposition (ALD), (b) various types of reactive-ion etching (RIE) and other types of etching processes, (c) photoresist (PR)-based photolithography, (d) liftoff, (e) hard-mask (HM)-based lithography, and (f) various processes of mask removal, such as but not limited to photoresist asking, photoresist stripping and HM etching.

At a hard mask and mesa (HMM) pattern formation step 1, a dielectric layer such as silicon-dioxide (SiO₂) layer, referred to herein as a layer 102, is deposited on layer 34, and subsequently, a PR 100 is patterned at predefined positions on the surface of layer 102.

At a selective mesa etching step 2, a stack comprising layers 102 and 34, and TJ 44, is etched, so that layer 45 is exposed. At a mask-removal step 3, PR 100 and layer 102 are removed so that layer 34 and TJ 44 are patterned on layer 45.

At an epitaxial-layer (EPI) regrowth step 4, layer 31 is deposited on layer 34. In some embodiments, layer 31 of lower DBR 78 comprises an n-type semiconductor compound layer (e.g., made from InP, or InAlGaAs) having a lattice that is matched with the lattice of InP layers or substrates. In other embodiments, layer 31 of lower DBR 78 may comprise a few pairs of epitaxial n-doped DBR, also referred to herein as nDBR, similar to the layers of ED 55.

At a contact deposition and patterning step 5, contacts 91, made from any suitable metal alloy (e.g., gold-germanium nickel gold (AuGe/Ni/Au alloys)), are deposited (e.g., using PVD or e-beam evaporator) and patterned (e.g., using lithography and RIE processes) at predefined positions on the surface of layer 31. In some embodiments, contacts 91 are configured to conduct electrical current of current path 64, between layers 31 and 89 shown in FIG. 1 above. At a dielectric DBR formation step 6, DD 66 is formed by depositing pairs of layers. As described in FIG. 1 above, DD 66 comprises repetitive pairs of high- and low-index materials, wherein the thickness of each layer is a quarter of the local wavelength of the light emitted by AR 33. In the example of FIG. 2, DD 66 comprises repetitive pairs of an amorphous-silicon layer and a SiO₂ layer.

In some embodiments, after step 6 (which concludes the formation of lower DBR 78), light-producing stack of layers (e.g., AR 33, layer 45 and TJ 44) and both upper DBR 79 and lower DBR 78 are formed, but are not electrically connected to one another or to BSD 12.

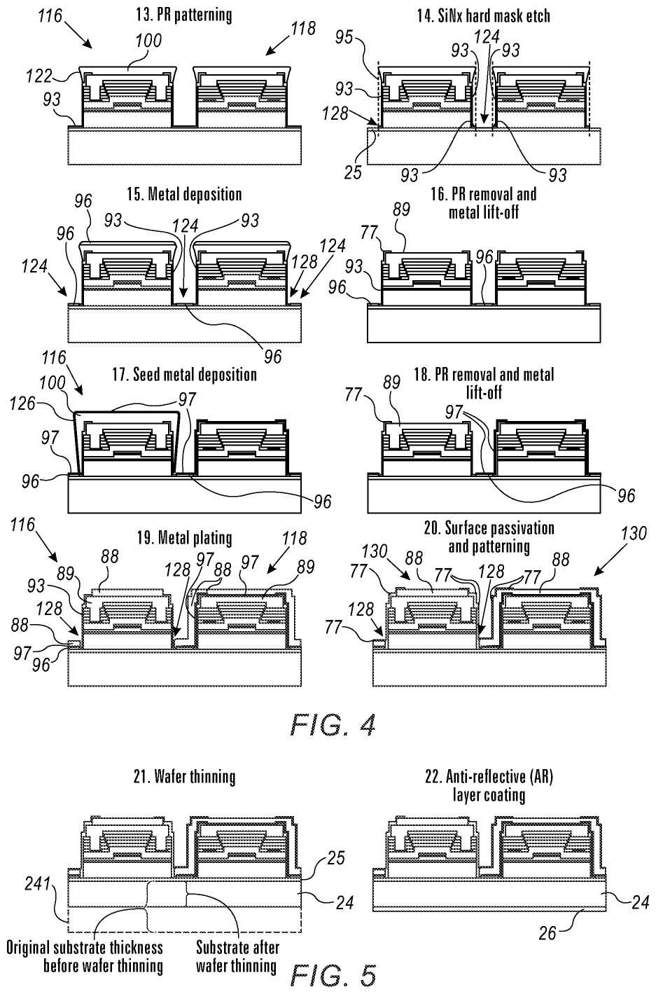

FIGS. 3-6 are diagrams that schematically illustrate a sectional view of a process sequence for producing module 11, in accordance with an embodiment that is described herein. In some embodiments, after the formation of the light-producing stack of layers (AR 33, layer 45 and TJ 44), and both upper DBR 79 and lower DBR 78, as described in FIG. 2 below, the process sequence of FIGS. 3 and 4, describes the formation of electrically connecting layers, such as layers 88 and 89, of VD 22. Reference is now made to FIG. 3. At a via etching step 7, DD 66 is patterned, e.g., using lithography and etching processes, so as to expose contacts 91 formed at step 5 above. At a first intra-cavity metal formation step 8, layer 89 is formed using a process sequence comprising: (a) seed metal deposition (e.g. using a PVD or sputtering process) and patterning (e.g., using lithography and etching processes) metal seed layer (which is thin and is therefore not shown), and (b) depositing (e.g. using an EP or ECP process) and patterning (e.g., using lithography and etching processes) a bulk metal layer on the seed layer.

In some embodiments, layer 89 comprises a stack of the seed and bulk metal layers. In some embodiments, layers 88 (shown in FIG. 1 above) and 89 are configured to: (i) conduct the electrical current between the light-producing stack of layers (AR 33, layer 45 and TJ 44) and BSD 12, and (ii) conduct excess heat produced during the emission of light beam 32.

At a HM pattern formation step 9, a SiNₓ passivation layer 77 (described in FIG. 1) and a PR 100 are deposited, and patterned. In some embodiments, the HM is required for protecting some layers of VD 22 during the following etching. At a deep etching step 10, deep etching of passivation layer 77, the light-producing stack of layers, and the DBRs (i.e., lower DBR 78 and upper DBR 79) is carried out, so as to divide VD 22 into two sections, a section 116 will be connected to anode 16 and a section 118 will be connected to cathode 18. In some embodiments, the deep etching step exposes layer 25 and forms a gap 117 separating between sections 116 and 118.

In some embodiments, in section 116 the light-producing stack of layers is electrically connected (via layer 31 and contacts 91) to layer 89, due to the via etching and filling in steps 7 and 8, respectively. Contrary to that, in section 118 DD 66 disconnects between contacts 91 and layer 89, so that the light-producing stack of layers is electrically disconnected and cannot emit light beam 32. In such embodiments, when VD 22 receives electrical current from BSD 12, light beam 32 is emitted solely from section 116, as shown in FIG. 1 above.

At a PR removal step 11, PR 100 is removed from passivation layer 77 of sections 116 and 118. At a passivation formation and opening step 12, a second passivation layer 93 (which typically has a SiNₓ compound identical to that of passivation layer 77) is formed on the external walls of sections 116 and 118 and on layer 25. Moreover, passivation layer 77 is patterned so as to open a section of passivation layer 77 for exposing layer 89. Note that step 12 comprises multiple processes that may be carried out using any suitable sequence.

Reference is now made to FIG. 4. At a PR pattern definition step 13, PR 100 is patterned on sections 116 and 118. Note that PR 100 has a reentrant profile 122 for patterning a first section of layer 93 formed on layer 25. At a passivation etching step 14, the first section 124 of layer 93 (defined in step 13) is etched, so as to expose layer 25. Note that, due to the aforementioned reentrant profile of PR 100, a second section 128 of layer 93 that is in close proximity to sections 116 and 118, remains on layer 25. For the sake of conceptual clarity, a dashed line (which is virtual) separates between the etched first section 124, and second section 128, in which layer 93 is not etched.

At a conductive layer deposition step 15, a layer 96, typically made from a metal alloy, is deposited on first section 124 and on PR 100. In some embodiments, layer 93 constitutes a hard mask for the formation of layer 96 at second section 128 of layer 93 described in step 114 above.

In other embodiments, layer 96 may comprise any other suitable type of conductive layer, other than the aforementioned metal alloy.

At a conductive layer liftoff step 16, layer 96 is lifted off by removing PR 100 using any suitable liftoff process. At a seed metal deposition step 117, PR 100 is patterned on section 116 and a seed layer 97 is deposited on PR 100. Note that PR 100 has a reentrant profile 126 to enable the deposition of seed layer 97 on layer 96.

At a seed liftoff step 18, PR 100 is removed and seed layer 97 is lifted-off, so that seed layer remains solely on layer 96. At a second intra-cavity metal formation step 19, layer 88 (typically made from gold or copper or any other suitable metal or metallic alloy) is formed using an EP or ECP plating process. Note that in electroplating processes the metal may be formed solely on conductive surfaces. In an embodiment shown in step 19, layer 88 is formed on seed layer 97, and on layer 89, but is not formed on passivation layers 77 and 93. In this embodiment, layer 88 is formed on the wall of section 118 (covered by seed layer 97), but is not formed on the wall of section 116 and in second section 128, which are covered by passivation layers 77 and 93. Note that section 116 is electrically disconnected from the conductive layers, such as layers 88, and 96, and seed layer 97.

At a surface passivation and patterning step 20, an additional passivation layer 77 is deposited on the entire surface of VD 22, and an opening 130 is etched so as to expose a section of layer 88. Note that passivation layers 77 and 93 are preventing any electrical contact between section 116 and the conductive layers, such as layers 88, and 96, and seed layer 97, particularly in second section 128.

Reference is now made to FIG. 5. At a wafer thinning step 21, the aforementioned InP wafer is thinned away using a thinning process (e.g., by backgrinding or wet etching), so as to reduce the thickness of substrate 24. In the example of step 21, the distance between layer 25 and a surface 241 shows the original thickness of substrate 24, so that the thinning process reduces about half, or any other suitable fraction, of the original thickness of substrate 24.

At an anti-reflecting coating step 22, AR layer 26 is coated on the surface of substrate 24. As described in FIG. 1 above, AR layer 26 is configured to prevent reflection of light beam 32 from the interface between substrate 24 surface and air, back into VD 22.

FIGS. 2-5 describe the production of multiple VDs 22 on substrate 24. After passivation and patterning step 20, VDs 22 are ready for assembling and packaging with BSD 12, so as to complete the production of module 11.

FIG. 6 is a diagram that schematically illustrates a sectional view of a process sequence for assembling VD 22 on BSD 12 for producing module 11, in accordance with an embodiment that is described herein.

Reference is now made to an inset 140, showing a top-view of an InP wafer 101, typically having a diameter of about 3″ or 4″ or any other suitable size or shape. In some embodiments, dicing streets 98 are defined for physically separating between adjacent dies 132 of VCSELs.

In the example of FIG. 6, each die may comprise a single VCSEL, such as VD 22 shown in FIG. 1. In other embodiments, each die may comprise multiple VCSELs arranged in a random or non-ordered array (not shown) or in an ordered array, such as an array 135. In such embodiments, each VCSELs may have two concentric round shapes, the outer round shape is referred to herein as mesa (described in FIG. 1 above), and the inner round shape represented in inset 140 by the term “BTJ” indicates the aperture of TJ 44.

Reference is now made to the general view of FIG. 6. At a die separation step 23, substrate 24 of InP wafer 101, and optionally some layers produced in FIGS. 3 and 4 above, are diced in dicing streets 98, so as to separate the dies formed on InP wafer 101 into a plurality of single VDs 22.

At a bump formation step 24, bumps 20 are formed on anodes 16 and cathodes 18 of BSD 12. In the example of step 24, bumps 20 are shown on a single pair of anode 16 and cathode 18, but such bump production processes are typically carried out in wafer level on all anodes 16 and cathodes 18 produced on silicon wafer 14 having a typical diameter of 12,” or any other suitable diameter.

At an assembling step 25, a die comprising multiple VDs 22 (e.g., array 135) or, in the present example, a single VD 22 device is flipped (up-side-down) and subsequently mounted on and coupled to BSD 12. In some embodiments, layer 88, which is exposed in openings 130 of section 116, is bonded to bump 20 that was formed (in step 22) on anode 16. Similarly, layer 88, which is exposed in openings 130 of section 118, is bonded to bump 20 that was formed (in step 22) on anode 18.

Note that in other processes of VCSEL integration on backplane silicon drivers (BSDs), the III-V semiconductor substrate may be removed (e.g., by wet etching) and various types of epitaxial or other layers may be formed on top of thin and brittle III-V epitaxial film (thickness smaller than about 15 um) to produce components of the VCSEL, such as an upper DBR. Such process is challenging and often gives rise to wafer breakage and low process yield. In the process of module 11, however, substrate 24 is not removed, hence the process does not involve handling or processing of a thin III-V epitaxial wafer, hence the wafer breakage can be minimized and process yield can be improved.

In some embodiments, after concluding step 25, BSD 12 and VD 22 are electrically connected, so that by applying power to BSD 12, VD 22 may receive electrical current from anode 16 and cathode 18, and VD 22 may emit light beam 32 by activating current paths 62 and 64. As described in FIG. 1 above, multiple VDs 22 are assembled on BSD 12 and one or more VDs 22 are selectively powered based on the routing of electrical traces 105. Such integrated modules may be implemented in mobile devices or may be movable, and therefore, it is important to provide module 11 with improved mechanical stability, heat dissipation, and electrical isolation from the environment and between some adjacent conductive components thereof.

At a filler formation step 26 that concludes the production method of module 11, filler 60 is produced by immersing module 11 in a liquid polymer, and subsequently, the polymer is hardened to form a solid state filler 60. In other embodiments, filler 60 may comprise any suitable materials other than polymer, or combined with polymer, using any suitable production process.

In some embodiments, filler 60 improves the mechanical stability of module 11, for example, by preventing relative movement between VD 22 and BSD 12. Moreover, filler 60 is configured to prevent deformation of module 11, such as bending of VD 22 relative to BSD 12, or any disconnection between layers or components of module 11 (e.g., disconnection between bump 20 and layer 88).

In some embodiments, filler 60 comprises electrically insulating materials, and is therefore, configured to prevent undesired electrical leaks between module 11 and the environment, and between adjacent components and/or layers of module 11. In some embodiments, filler 60 is further configured to physically isolate module 11 from humidity and other undesired environmental conditions.

In some embodiments, after concluding step 25 or step 26, one or more optical elements, such as but not limited to micro-lens (e.g., lens 28 shown in FIG. 1 above), or diffractive optical elements (DOEs) may be integrated with substrate 24. For example, lens 28 or another suitable type of optical element may be formed on top of substrate 24 before or after the formation of AR layer 26. These optical elements may be used for shaping and/or steering and/or otherwise manipulating light beam 32. Note that the optical elements may also be produced in or integrated with RCPD-on-Si devices for collecting the light beam detected by the RCPD.

This particular process (shown in FIGS. 2-6) for producing module 11 is simplified and shown by way of example, in order to illustrate certain problems that are addressed by embodiments of the disclosed techniques and to demonstrate the application of these embodiments in enhancing the performance of such a module. Embodiments of the present invention, however, are by no means limited to this specific sort of example process flow, and the principles described herein may similarly be applied to other sorts of process flows for producing integrated VCSELs, other sorts of lasers, or other sorts of light emitting modules.

Although the embodiments described herein mainly address integration of light emitting and/or receiving devices and/or modules, the methods and systems described herein can also be used in other applications, such as III-V-on-Silicon electric and photonic integrated circuits or heterogeneous integration of Si-CMOS circuits and III-V hetero junction bipolar transistor (HBT) for high performance mixed signal applications.

It will thus be appreciated that the embodiments described above are cited by way of example, and that the following claims are not limited to what has been particularly shown and described hereinabove. Rather, the scope includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An optoelectronic device, comprising:
a semiconductor substrate doped with a first level of n-type dopants;
a contact semiconductor layer disposed over the semiconductor substrate and doped with a second level of n-type dopants, larger than the first level;
an upper distributed Bragg-reflector (DBR) stack disposed over the contact semiconductor layer and comprising alternating first and second epitaxial semiconductor layers having respective first and second indexes of refraction that differ from one another in a predefined wavelength band;
a set of epitaxial layers disposed over the upper DBR, wherein the set of epitaxial layers comprises one or more III-V semiconductor materials and defines:
a quantum well structure; and
a confinement layer; and
a lower DBR stack disposed over the set of epitaxial layers, opposite the upper DBR, and comprising alternating dielectric and semiconductor layers.

2. The device according to claim 1, wherein the quantum well structure is configured to emit a light beam having a wavelength in the predefined wavelength band.

3. The device according to claim 2, wherein at least one of: (i) the semiconductor substrate, (ii) the contact semiconductor layer, and (iii) the set of epitaxial layers, comprises indium-phosphide, and wherein the emitted light beam has a wavelength between 1.2 μm and 2 μm.

4. The device according to claim 2, wherein at least one of: (i) the semiconductor substrate, (ii) the contact semiconductor layer, and (iii) the set of epitaxial layers, comprises gallium-antimony, and wherein the emitted light beam has a wavelength larger than 2 μm.

5. The device according to claim 2, wherein at least one of: (i) the semiconductor substrate, (ii) the contact semiconductor layer, and (iii) the set of epitaxial layers, comprises gallium-arsenide, and wherein the emitted light beam has a wavelength between 0.63 μm and 1.1 μm.

6. The device according to claim 2, wherein at least one of: (i) the semiconductor substrate, (ii) the contact semiconductor layer, and (iii) the set of epitaxial layers, comprises gallium-nitride, and wherein the emitted light beam has a wavelength smaller than 0.6 μm.

7. The device according to claim 2, and comprising electrodes, coupled to apply an excitation current to the quantum well structure.

8. The device according to claim 7, wherein the electrodes comprise a first electrode and a second electrode, and comprising (i) a first bump, electrically coupled between the first electrode and the contact semiconductor layer, and (ii) a second bump coupled between the second electrode and an additional contact semiconductor layer, and wherein the first and second bumps are configured to conduct the excitation current applied to the quantum well structure.

9. The device according to claim 1, wherein the lower DBR comprises, in addition to the alternating dielectric and semiconductor layers, alternating third and fourth epitaxial semiconductor layers having respective third and fourth indexes of refraction that differ from one another in the predefined wavelength band.

10. The device according to claim 1, wherein the quantum well structure is configured to detect light in the predefined wavelength.

11. The device according to claim 10, and comprising electrodes, coupled to receive, from the quantum well structure, a signal indicative of the detected light beam.

12. A method for producing an optoelectronic device, the method comprising:
disposing, over a semiconductor substrate doped with a first level of n-type dopants, a contact semiconductor layer and doping the contact semiconductor layer with a second level of n-type dopants, larger than the first level;
disposing, over the contact semiconductor layer, an upper distributed Bragg-reflector (DBR) stack comprising alternating first and second epitaxial semiconductor layers having respective first and second indexes of refraction that differ from one another in a predefined wavelength band;
disposing, over the upper DBR, a set of epitaxial layers, comprising one or more III-V semiconductor materials and defining:
a quantum well structure; and
a confinement layer; and
disposing, over the set of epitaxial layers, a lower DBR stack opposite the upper DBR, the lower DBR comprising alternating dielectric and semiconductor layers.

13. The method according to claim 12, wherein disposing the set of epitaxial layers comprises producing the quantum well structure for emitting a light beam having a wavelength in the predefined wavelength band.

14. The method according to claim 13, and comprising producing at least one of: (i) the semiconductor substrate, (ii) the contact semiconductor layer, and (iii) the set of epitaxial layers, with indium-phosphide for emitting the light beam having a wavelength between 1.2 μm and 2 μm.

15. The method according to claim 13, and comprising producing at least one of: (i) the semiconductor substrate, (ii) the contact semiconductor layer, and (iii) the set of epitaxial layers, with gallium-arsenide for emitting the light beam having a wavelength between 0.63 μm and 1.1 μm.

16. The method according to claim 13, and comprising producing electrodes, which are coupled to apply an excitation current to the quantum well structure.

17. The method according to claim 12, wherein disposing the lower DBR comprises, in addition to the disposed alternating dielectric and semiconductor layers, disposing alternating third and fourth epitaxial semiconductor layers having respective third and fourth indexes of refraction that differ from one another in the predefined wavelength band.

18. The method according to claim 12, wherein disposing the set of epitaxial layers comprises producing the quantum well structure for detecting light in the predefined wavelength.

19. The method according to claim 18, and comprising producing electrodes, which are coupled to receive from the quantum well structure, a signal indicative of the detected light beam.

20. A method, comprising:
operating an optoelectronic device comprising: (i) a semiconductor substrate doped with a first level of n-type dopants, (ii) a contact semiconductor layer disposed over the semiconductor substrate and doped with a second level of n-type dopants, larger than the first level, (iii) an upper distributed Bragg-reflector (DBR) stack disposed over the contact semiconductor layer and comprising alternating first and second epitaxial semiconductor layers having respective first and second indexes of refraction that differ from one another in a predefined wavelength band, (iv) a set of epitaxial layers disposed over the upper DBR, wherein the set of epitaxial layers comprises one or more III-V semiconductor materials and defines: (a) a quantum well structure, and (b) a confinement layer, and (v) a lower DBR stack disposed over the set of epitaxial layers, opposite the upper DBR, and comprising alternating dielectric and semiconductor layers; and
applying an excitation current to the quantum well structure for emitting a light beam having a wavelength in the predefined wavelength band.
